(19) United States
(12) Patent Application Publication
(10) Pub. No.: US 2014/0166965 A1
(43) Pub. Date: Jun. 19, 2014

(54) RESISTIVE MEMORY DEVICE AND FABRICATION METHOD THEREOF

(71) Applicant: SK HYNIX INC., Gyeonggi-do (KR)

(72) Inventors: Jung Won SEO, Gyeonggi-do (KR); Hae Chan PARK, Gyeonggi-do (KR); Myoung Sub KIM, Gyeonggi-do (KR); Sung Bin HONG, Gyeonggi-do (KR); Se Ho LEE, Gyeonggi-do (KR); Seung Yun LEE, Gyeonggi-do (KR)

(73) Assignee: SK Hynix Inc., Gyeonggi-do (KR)

(21) Appl. No.: 13/846,129

(22) Filed: Mar. 18, 2013

(30) Foreign Application Priority Data
Dec. 14, 2012 (KR) 10-2012-0146382

(51) Int. Cl. H01L 45/00

(52) U.S. Cl. CPC H01L 45/06; H01L 45/1608
USPC 257/4; 438/382

(57) ABSTRACT

A resistive memory device may include a bottom structure, a memory cell structure disposed on the bottom structure, and a data storage material disposed to surround an outer sidewall of the memory cell structure.

### CROSS-REFERENCES TO RELATED APPLICATION

The present application claims priority under 35 U.S.C. 119(a) to Korean application number 10-2012-0146382, filed on Dec. 14, 2012, in the Korean Intellectual Property Office, which is incorporated herein by reference in its entirety.

### BACKGROUND

1. Technical Field

Exemplary embodiments of the present invention relate to a semiconductor fabrication technology, and more particularly, to a resistive memory device and a method of fabricating the same.

2. Related Art

As a size of semiconductor memory devices has become smaller, critical dimension (CD) for formation of each component of the semiconductor devices has also been reduced.

Notwithstanding shrinkage of the design rule, an equipment margin such as direct alignment accuracy (DAA) in fabrication equipment and a CD tolerance are limited at a certain level, and thus an overlay margin in fine pattern formation may not have been secured.

Resistive memory devices are a kind of non-volatile memories under development. A unit memory cell of a memory resistive memory includes an access device and a data storage material. The memory resistive memory selects a memory cell to be accessed through the access device and changes a resistance state of the data storage material electrically connected to the access device in accordance with data to be stored. Typical examples of the resistive memory devices are phase-change random-access memories (PRAMs), resistive random-access memories (RRAMs), and magnetoresistive random-access memories (MRAMs).

Among the resistive memory devices, the PCRAMs determine data to be stored in the selected memory cell based on a resistance state of a phase-change material (i.e., data storage material). By heating a phase-change material, the phase of the phase-change material may be changed, and thus the resistance state may be controlled. In general, to miniaturize the device, the PCRAMs are formed using a method of forming a nitride layer on an entire prepared substrate in which a bottom structure is formed, patterning the nitride layer of a phase-change material formation region to be removed, and burying a phase-change material.

However, due to the limitation of the equipment margin or the CD tolerance as described above, variation of the resistance of the phase-change material may be enlarged, so that cell distribution variation may be increased. Also, Due to the same reason, the overlay margin in patterning of the nitride layer may not be ensured. Further, since the CD of the region where the phase-change material is to be formed is very small, the phase-change material may not be entirely buried within the region and a contact area with the bottom structure may not be significantly ensured, This causes the increase of contact resistance, and thus malfunction of the device may occur. Further, due to the increased contact resistance, it is required to increase a reset current.

Furthermore, as the reduction rate is increased, resistance of the device has to be reduced. However, the increase in the reduction rate shows rapid increase in resistance variation with respect to the same CD tolerance and change in characteristics between the same devices is increasing.

### SUMMARY

In accordance with an aspect of an exemplary embodiment, a resistive memory device may include a bottom structure, a memory cell structure disposed on the bottom structure, and a data storage material disposed to surround an outer sidewall of the memory cell structure.

In accordance with another aspect of an exemplary embodiment, a resistive memory device may include a bottom structure, a first electrode disposed on the bottom structure, an insulating layer disposed on a predetermined region of the first electrode, a data storage material disposed to surround an outer sidewall, a bottom, and a top of the insulating layer, and a second electrode being in contact with the top of the insulating layer.

In accordance with another aspect of an exemplary embodiment, a method may include forming memory cell structures on a semiconductor substrate in which a bottom structure is formed, sequentially forming a data storage material layer and a capping layer on the semiconductor substrate, and forming sidewall spacers including the data storage material layer and the capping layer, wherein each of the sidewall spacers surrounds outer sidewalls of the memory cell structures.

In accordance with another aspect of an exemplary embodiment, a method may include forming first electrodes on the semiconductor substrate in which a bottom structure is formed, forming a capping layer on the semiconductor substrate including the first electrode, removing the capping layer of a predetermined region to form spacer holes, forming a first data storage material layer on the semiconductor substrate including the spacer holes, forming insulating patterns being buried within each of the spacer holes, forming second data storage material patterns covering each of the insulating patterns, and forming second electrodes being in contact with each of the second data storage material patterns.

These and other features, aspects, and embodiments are described below in the section entitled “DETAILED DESCRIPTION”.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIGS. 1 to 6 are cross-sectional views illustrating a method of fabricating a resistive memory device in accordance with an exemplary embodiment of the present invention;

FIG. 7 is a perspective view illustrating a resistive memory device fabricated by an exemplary embodiment of the present invention; and

FIGS. 8 to 15 are cross-sectional views illustrating a method of fabricating a resistive memory device in accordance with another embodiment of the present invention.

### DETAILED DESCRIPTION

Hereinafter, exemplary embodiments will be described in greater detail with reference to the accompanying drawings.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing. In the drawings, lengths and sizes of layers and regions may be exaggerated for clarity. Throughout the disclosure, reference numerals correspond directly to the like numbered parts in the various figures and embodiments of the present invention. It should be readily understood that the meaning of “on” and “over” in the present disclosure should be interpreted in the broadest manner such that “on” means not only “directly on” but also “on” something with an intermediate feature(s) or a layer(s) therebetween, and that “over” means not only directly on top but also on top of something with an intermediate feature(s) or a layer(s) therebetween.

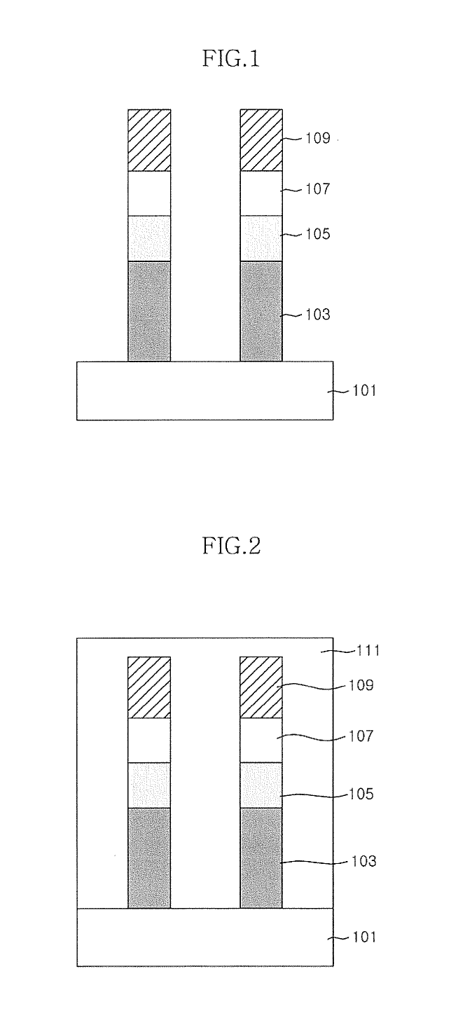

FIGS. 1 to 6 are cross-sectional views illustrating a method of fabricating a resistive memory device in accordance with an exemplary embodiment of the present invention.

Referring to FIG. 1, A structure in which a selection device 103, a first electrode 105, an insulating layer 107, and a second electrode 109 are sequentially stacked on a semiconductor substrate 101 including a bottom structure are formed. Here, the bottom structure may include a word line. The first electrode 105 may be a lower electrode and the second electrode 109 may be an upper electrode. The first electrode 105 and the second electrode 109 are formed to sufficient thicknesses using a material having low resistivity to reduce a contact resistance with a data storage material to be formed in a subsequent process. Specifically, the second electrode 109 may be formed in a sufficient size to ensure an etching margin when a bit line is formed in a subsequent process.

As the selection device 103, any device that enables selection of a memory cell by a voltage supplied through a word line may be adopted. For example, the selection device 103 may be a diode.

The insulating layer 107 may be used to insulate between the first electrode 105 and the second electrode 109. For example, the insulating layer 107 may be formed of oxide.

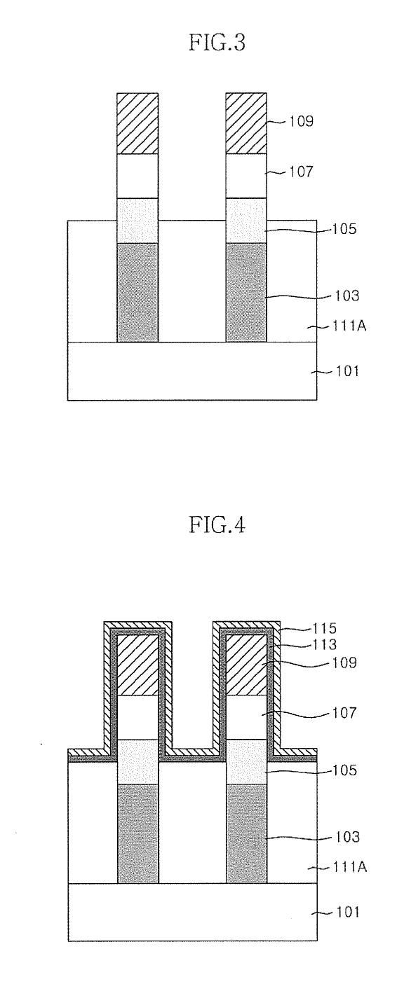

As illustrated in FIG. 2, a first inter-layer dielectric layer 111 is formed on the semiconductor substrate including the second electrode 109. Then, as illustrated in FIG. 3, the first inter-layer dielectric layer 111 is recessed. The first inter-layer dielectric layer 111 has to be recessed to a height so that selection devices 103 are insulated from each other. Therefore, the height of the recessed first inter-layer dielectric layer 111A is larger than that of the selection device 103, and the first inter-layer dielectric layer 111 has to be recessed to the height so that the first electrode 105 is not entirely covered with the first inter-layer dielectric layer 111. Here, an outer sidewall of the first electrode 105 exposed by the recess of the first inter-layer dielectric layer 111A becomes a data storage material formation region.

In the exemplary embodiment, the outer sidewall of the first electrode 105 may be exposed by a certain length so that a data storage material to be formed in a subsequent process is sufficiently in contact with the first electrode 105 to reduce contact resistance. Therefore, the exposed length of the outer sidewall of the first electrode 105 may be determined by considering the contact resistance with the data storage material.

As illustrated in FIG. 4, a data storage material layer 113 and a capping layer are sequentially formed on the semiconductor substrate including the recessed first inter-layer dielectric layer 111A. The data storage material layer 113 may be formed by uniformly depositing the data storage material to have a preset thickness. The capping layer 115 may be uniformly deposited to a thickness sufficient to protect the data storage material layer 113. For example, the capping layer 115 may be formed of nitride, and the data storage material layer 113 may be a phase-change material.

As illustrated in FIG. 5, the capping layer 115 and the data storage material layer 113 are etched by performing an anisotropic etching process. Therefore, a sidewall spacer having a double structure of the data storage material layer 113A and the capping layer 115A is formed on the outer sidewall of the first electrode 105, the insulating layer 107, and the second electrode 109.

When the anisotropic etching process is performed, the data storage material layer 113 may be over-etched to be separated between memory cells and to be prevented from being lost in a subsequent process for bit line formation. Thus, the sidewall spacer 113A and 115A may be disposed from a height lower than a top of the second electrode 209 by a predetermined length toward a bottom thereof.

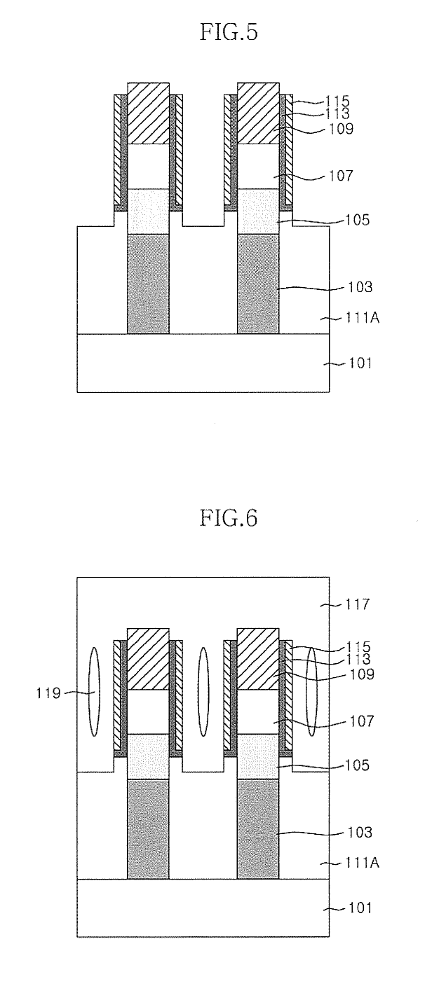

As illustrated in FIG. 6, a second inter-layer dielectric layer 117 is formed on the semiconductor substrate including the sidewall spacer 113A and 114A to insulate between the memory cells. Here, the second inter-layer dielectric layer 117 may be formed using a material having a poor gap-fill property so that an air gap (a void) 119 may be generated in the inside of the second inter-layer dielectric layer 117. The air gap 119 may serve to reduce thermal diffusion of the data storage material and to prevent disturbance between the memory cells.

After the second inter-layer dielectric layer 117 is formed, the second inter-layer dielectric layer 117 may be etched to expose a top of the second electrode 109, and a>bit line connected to the second electrode 109 may be formed.

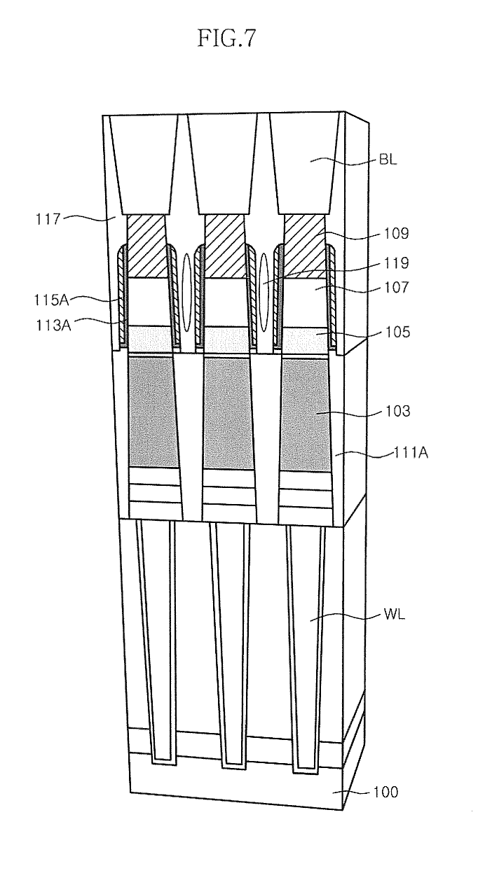

FIG. 7 is a perspective view illustrating a resistive memory device fabricated by the exemplary embodiment of the present invention.

Referring to FIG. 7, a bottom structure including a word line WL is disposed on a semiconductor substrate 100. A selection device 103 is disposed on the word line WL. A memory cell structure including a first electrode 105, an insulating layer 107, and a second electrode 109 is disposed on the word line WL. The selection device 103 is insulated from each other by a first inter-layer dielectric layer 111A.

A data storage material layer 113A is disposed on an outer sidewall of the memory cell structure 105, 107, and 109 in a cylindrical structure. The data storage material layer 113A may be disposed in a structure to cover the first electrode 105 and the second electrode 109 by a predetermined length. An outer sidewall of the data storage material layer 113A may be protected by a capping layer 115A. Further, unit memory cell including the memory cell structure 105, 107, and 109 and the data storage material layer 113A are insulated by the second inter-layer dielectric layer 117.

A bit line BL may be disposed on the second electrode 109.

As described above, in the resistive memory device in accordance with an exemplary embodiment, the data storage material layer 113A may be formed on an outer sidewall of a specific structure, preferably, an outer sidewall of the memory cell structure in a cylindrical structure using a sidewall spacer formation process that includes a deposition process and an anisotropic etching process. That is, since the data storage material layer 113A may not be formed through a fine pattern formation and burying process but may be uniformly formed on a surface of the specific structure to a thin thickness through the deposition process, the data storage material layer 113A may be errorlessly uniformly formed without restriction for limitation of an equipment margin or a CD tolerance.

Further, an air gap 119 may be introduced between adjacent memory cells. In this case, heat emitted in the data storage material layer 113A is prevented from being diffused into an adjacent memory cell. Thus, disturbance between memory cells may be reduced and a more reliable operation may be performed.

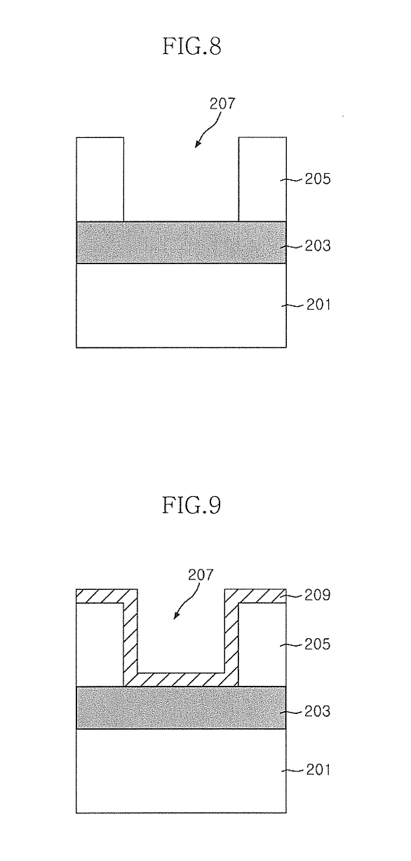

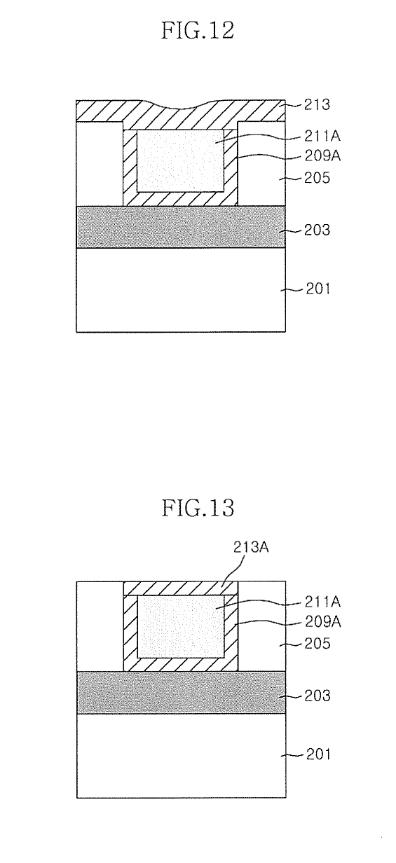

FIGS. 8 to 15 are cross-sectional views illustrating a method of fabricating a resistive memory device in accordance with another exemplary embodiment of the present invention.

First, as illustrated in FIG. 8, a first electrode 203 and a capping layer 205 are formed on a semiconductor substrate 201 in which a bottom structure is formed. A predetermined portion of the capping layer 205 is patterned to form a spacer hole 207.

Here, the first electrode 203 is formed using a material having low resistivity to a sufficient thickness to reduce a contact resistance with a data storage material to be formed in a subsequent process. The capping layer 205 may be formed of nitride.

As illustrated in FIG. 9, a first data storage material layer 209 is formed on the semiconductor substrate including the spacer hole 207. The first data storage material 209 may be uniformly formed to have a preset thickness through a deposition process. For example, the first data storage material layer 209 may be a phase-change material.

As seen from FIG. 9, the first data storage material layer 209 is not formed to be entirely buried in the spacer hole 207 but thinly formed along a surface of the capping layer 205. Therefore, a diameter of the spacer hole 207 is mutually irrelevant to a thickness of the first data storage material layer 209, and this means that the first data storage material layer 209A is not necessary to be formed corresponding to the diameter of the spacer hole 207, which may be determined depending on the design rule.

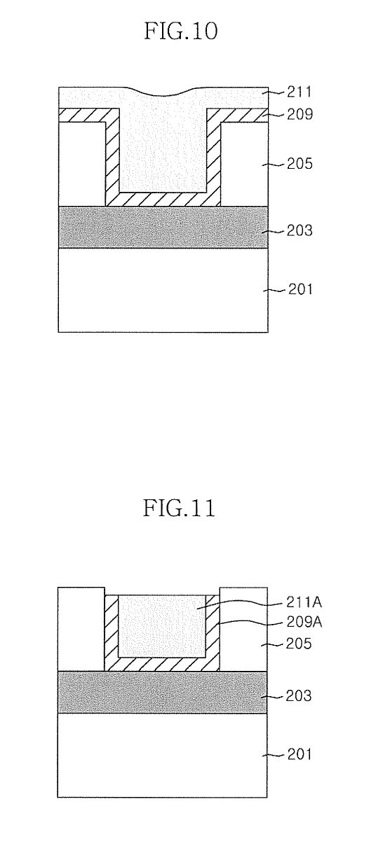

As illustrated in FIG. 10, an insulating layer 211 is formed on the semiconductor substrate including the first data storage material layer 209. As illustrated in FIG. 11, the insulating layer 211 and the first data storage material layer 209 are blanket-etched to expose a top of the capping layer 205. Here, an etching process may be performed using a material having higher etch-selectivity on the insulating layer 211 and the first data storage material layer 209 than that on the capping layer 205. Therefore, top levels of the first data storage material layer 209A and the insulating layer 211A remaining in the spacer hole 207 is lower than that of the capping layer 205 by a predetermined height.

Subsequently, a second data storage material layer 213 is formed on the semiconductor substrate including the etched first data storage material 209A and insulating layer 211A. The second data storage material layer 213 may be formed using the same material as the first data storage material layer 209A having the same composition ratios or different composition ratios. Alternatively, the second data storage material layer 213 may be formed using the different material from the first data storage material layer 209A. However, the first and second data storage material layers 209A and 213 have to include a material having the same data storage property.

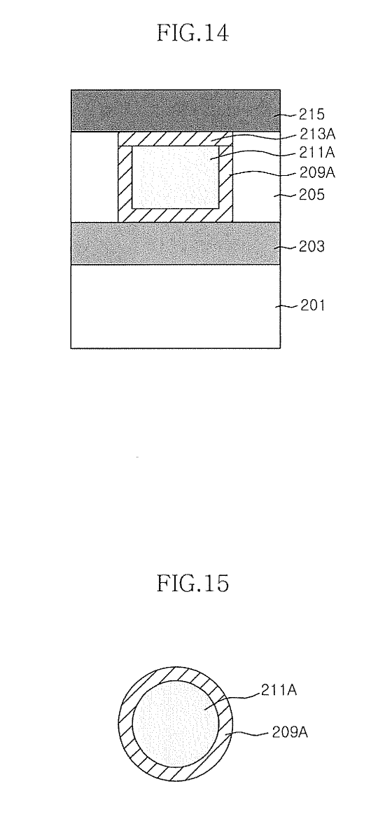

Then, as illustrated in FIG. 13, a planarization process is performed on the second data storage material layer 213 to expose the capping layer 205. As illustrated in FIG. 14, a second electrode 215 is formed on the semiconductor substrate including the data storage material layer 209. The second electrode 215 is formed using a material having low resistivity to reduce a contact resistance with the second data storage material layer 213k Further, the second electrode 215 may be formed in a thickness that may ensure an etching margin when a bit line is formed in a subsequent process.

As a result, the data storage material layers 209A and 213A may have a structure in which a bottom of the data storage material layers 209A and 213A is in full contact with the first electrode 203, a top thereof is in full contact with the second electrode 215, and the insulating layer 211A is buried in a space confined by the data storage material layers 209A and 213A as illustrated in FIG. 15 (top view).

In the resistive memory devices illustrated in FIGS. 1 to 7 and FIGS. 8 to 15, the data storage material layer 209A may be thinly formed and may have sufficient contact areas with the first and second electrodes 203 and 215. Therefore, the contact resistance may he reduced, thereby reducing a reset current and ensuring thermal stability.

Further, the forming of a fine pattern may not be required, and thus an equipment margin or CD tolerance may not be limited and the fabrication processes may become easy and simple so that fabrication efficiency may be maximized.

The above embodiment of the present invention is illustrative and not limitative. Various alternatives and equivalents are possible. The invention is not limited by the embodiment described herein. Nor is the invention limited to any specific type of semiconductor device. Other additions, subtractions, or modifications are obvious in view of the present disclosure and are intended to fall within the scope of the following claims.

What is claimed is:

1. A resistive memory device, comprising:
a bottom structure;
a memory cell structure disposed on the bottom structure; and
a data storage material disposed to surround an outer sidewall of the memory cell structure.

2. The resistive memory device of claim 1, further comprising a selection device disposed to be in contact between the bottom structure and the memory cell structure.

3. The resistive memory device of claim 1, wherein the memory cell structure has a stacked structure of a first electrode, an insulating layer, and a second electrode.

4. The resistive memory device of claim 3, wherein the data storage material is disposed to cover an outer sidewall of the insulating layer, a predetermined portion of an outer sidewall of the first electrode, and a predetermined portion of an outer sidewall of the second electrode.

5. The resistive memory device of claim 1, further comprising a capping layer disposed to surround an outer sidewall of the data storage material.

6. The resistive memory device of claim 1, wherein the data storage material includes a phase-change material.

7. A resistive memory device, comprising:
a bottom structure;
a first electrode disposed on the bottom structure;
an insulating layer disposed on a predetermined region of the first electrode;
a data storage material disposed to surround an outer sidewall, a bottom, and a top of the insulating layer; and
a second electrode being in contact with the top of the insulating layer.

8. The resistive memory device of claim 7, further comprising a capping layer disposed to surround the outer sidewall of the data storage material.

9. The resistive memory device of claim 7, wherein the data storage material is a phase-change material.

10. A method of fabricating a resistive memory device, the method comprising:
forming memory cell structures on a semiconductor substrate in which a bottom structure is formed;
sequentially forming a data storage material layer and a capping layer on the semiconductor substrate; and
forming sidewall spacers including the data storage material layer and the capping layer, wherein each of the sidewall spacers surrounds outer sidewalls of the memory cell structures.

11. The method of claim 10, wherein each of the memory cell structures has a stacked structure of a first electrode, an insulating layer, and a second electrode.

12. The method of claim 11, wherein the sidewall spacers is formed by performing an anisotropic etching process so that the data storage material layer is remained to cover the insulating layer, and a predetermined portion of the outer sidewalls of the first electrode and the second electrode.

13. The method of claim 10, further comprising forming an inter-layer dielectric layer on the semiconductor substrate after the forming of the sidewall spacers.

14. The method of claim 13, wherein the inter-layer dielectric layer is formed so that air gaps are generated between the memory cell structures.

15. The method of claim 10, wherein the data storage material layer is formed of a phase-change material,

16. A method of fabricating a resistive memory device, the method comprising:
forming first electrodes on the semiconductor substrate in which a bottom structure is formed;
forming a capping layer on the semiconductor substrate including the first electrode;
removing the capping layer of a predetermined region to form spacer holes;
forming a first data storage material layer on the semiconductor substrate including the spacer holes;
forming insulating patterns being buried within each of the spacer holes;
forming second data storage material patterns covering each of the insulating patterns; and
forming second electrodes being in contact with each of the second data storage material patterns.

17. The method of claim 16, wherein the forming of the insulating patterns comprising:
forming an insulating layer on the semiconductor substrate including the first data storage material; and
blank-etching the insulating layer and the first data storage material layer to expose an upper surface of the capping layer, wherein surface levels of the first data storage material layer and the insulating layer buried in the spacer hole are lower than that of the capping layer

18. The method of claim 17, wherein the forming of the second data storage material patterns comprising:
forming a second data storage material layer on the semiconductor substrate including the insulating patterns; and
planarizing the second data storage material layer to expose the capping layer.

19. The method of claim 18, wherein each of the first data storage material layer and the second data storage material layer is formed of a phase-change material.

20. The method of claim 19, wherein the first data storage material layer and the second data storage material layer are formed of the same material, having the same composition ratios or different composition ratios, or of different materials.
